(19) United States
(12) Patent Application Publication
(10) Pub. No.: US 2011/0049505 A1
(43) Pub. Date: Mar. 3, 2011

(54) DEVICES AND METHOD FOR MANUFACTURING A DEVICE

(76) Inventors: Johannes Grabowski, Trochtelfingen (DE); Holger Hoefer, Sonnenbuehl (DE); Thomas Klaus, Tuebingen (DE); Gerald Hopf, Reutlingen (DE)

(21) Appl. No.: 12/871,666

(22) Filed: Aug. 30, 2010

(30) Foreign Application Priority Data
Aug. 31, 2009 (DE) 102009029040.0

(51) Int. Cl. H01L 23/48; H01L 21/44

(52) U.S. Cl. 257/41; 438/100; 257/E23.01; 257/E21.476

(57) ABSTRACT

A device includes a first semiconductor chip and a second semiconductor chip which are connected to each other in an electrically conductive manner via a bonding wire, the bonding wire having a contact to the first semiconductor chip at a first contact point and having a contact to the second semiconductor chip at a second contact point, and the device including a further bonding wire which has a further first contact point and a further second contact point, a maximum distance between the bonding wire and a direct connecting line between the first and second contact points perpendicular to the connecting line being greater than a further maximum distance between the further bonding wire and a further connecting line between the further first contact point and the further second contact point perpendicular to the further connecting line.

### CROSS REFERENCE

The present application claims the benefit under 35 U.S.C. §119 of German Patent Application No. 102009029040.0 filed on Aug. 31, 2009, which is expressly incorporated herein by reference in its entirety.

### BACKGROUND INFORMATION

A semiconductor chip situated on a module carrier is described in German Patent Application No. DE 197 03 639 A1. Connecting surfaces of the chip are connected to connecting surfaces of the module carrier via bonding wires which are manufactured using a ball/wedge bonding method, first ends of the bonding wires being first formed in a spherical shape (ball) using a bonding tool and subsequently welded to the connecting surfaces of the semiconductor chip, and second ends of the bonding wire being wedged and permanently welded to the connecting surfaces of the module carrier. The first ends (also referred to as starting points of the bonding method) are known as “balls” due to their at least sometimes spherical shape, while the second ends (also referred to as end points of the bonding method) are known as “wedges,” due to their crimped, wedge-shaped design. Bonds of this type are also used to contact capacitive sensors (in surface micromechanics or bulk micromechanics) or to connect to an evaluation chip in an electrically conductive manner, a plurality of bonding wires being used which, generally, are situated parallel to each other in an advantageous manner from the manufacturing point of view. It is then assumed that no further geometric changes are made to the bonding wires after bonding, and changes in the dielectric due to high symmetries are, in principle, not an issue. If these assumptions are not met in reality, an offset drift and/or temperature dependency of the offset occurs, for example due to deformation of individual bonding wires during manufacture and/or assembly of the system or due to thermal cyclic creep effects.

### SUMMARY

An example device according to the present invention and an example method according to the present invention for manufacturing a device, may have the advantage that the parasitic capacitances between adjacent bonding wires, i.e., in particular between the bonding wire and the further bonding wire, are substantially reduced without requiring additional installation space. This is achieved by increasing the average wire distance between the bonding wire and the further bonding wire in both devices according to the example embodiment of the present invention. The principle is based on the fact that the capacitance between two parallel conductors is reversed in the known manner in proportion to the hyperbolic area cosine of the wire distance between these two conductors, so that increasing the average wire distance causes the capacitance between the conductors to be reduced (known as the capacitance of the Lecher wires). In the example device according to the present invention, the wire distance is achieved either by the different sizes of the maximum distance and of the further maximum distance or by the different position of the maximum distance. The principle of the asymmetrical structure of two adjacent bonding wires is therefore identical in both devices according to the example embodiment of the present invention. In both cases, the increased distance is not produced by increasing the horizontal distance, but by increasing the vertical distance. In other words, the bonding wire and the further bonding wire have different heights (loop heights in the vertical direction or a different height shape (loop height shape) in the vertical direction, vertical direction meaning a direction perpendicular to the main extension plane of the connecting surfaces. Increased space requirements or repositioning of the connecting surfaces or a modified pitch (distance between component connections) of the connecting surfaces is therefore advantageously not required in either case, so that standard elements having a standard pitch, in particular, may be used as the first and/or second semiconductor chip. A difference in size between the maximum distance and the further maximum distance is achieved by the fact that the bonding wire, for example, is longer than the further bonding wire, so that the maximum height and the average curvature are inevitably greater in the bonding wire than in the further bonding wire. Alternatively, the different positions of the maximum distance in the bonding wire and the further bonding wire are achieved, for example, by orienting the bonding directions during manufacture of the bonding wire and the further bonding wire in directions that are diametrically opposed to each other. The assembly stability and, in particular, the vibration stability are advantageously increased, since the danger of a short-circuit of adjacent bonding wires or exceeding of the minimum distance, for example due to vibrations or impact, during manufacturing or during assembly, is reduced by the increased distance.

According to a preferred specific embodiment, it is provided that the further maximum distance is no more than 75 percent, preferably no more than 30 percent, and particularly preferably no more than 10 percent of the maximum distance, so that an adequate capacitive decoupling between the bonding wire and the further bonding wire is advantageously ensured, thereby reducing offset drifts due to parasitic capacitances over time or as a function of temperature between the bonding wires, thus improving the signal-to-noise ratio during signal transmission over the bonding wires.

According to a preferred specific embodiment, it is provided that the distance between the position of the maximum distance on the connecting line and the position of the further maximum distance on the further connecting line along the connecting line is at least 10 percent, preferably at least 20 percent, and particularly preferably at least 50 percent of the total length of the maximum distance on the connecting line and/or the distance between the position of the maximum distance on the connecting line, and the position of the further maximum distance on the further connecting line along the further connecting line is at least 10 percent, preferably at least 20 percent, and particularly preferably at least 50 percent of the total length of the further connecting line. The average distance between the bonding wire and the further bonding wire is thus advantageously increased without changing or increasing the total height of the bonding wire and the further bonding wire, so that the signal-to-noise ratio is improved in the manner described above.

According to a preferred specific embodiment, it is provided that the further first contact point has a contact between the further bonding wire and the first semiconductor chip and the further second contact point has a contact between the further bonding wire and the second semiconductor chip, making it possible to establish a two-wire electrical connection between the first semiconductor chip and the second semiconductor chip. However, it is also advantageously possible that the further first contact point has a contact between the further bonding wire and a third semiconductor chip, and/or the further second contact point has a contact between the further bonding wire and a fourth semiconductor chip, so that the parasitic capacitances between bonding wires which connect different semiconductor chips to each other may also be reduced.

According to a preferred specific embodiment, it is provided that the bonding wire includes a “ball/wedge bond” and the further bonding wire includes a further “ball/wedge bond,” the first contact point forming the “ball” of the “ball/wedge bond” and the second contact point forming the “wedge” of the “ball/wedge bond,” and the further first contact point forming the “wedge” of the further “ball/wedge bond” and the further second contact point forming the “ball” of the further “ball/wedge bond.” Thus, this advantageously makes a comparatively simple implementation of the system according to the present invention possible, since the position of the maximum height of the bonding wire (i.e., the maximum distance between the bonding wire and the connecting line perpendicular to the connecting position) is usually closer to the “ball” (i.e., to the starting point of the bonding process) than to the “wedge” (i.e., the end point of the bonding process). Consequently, an offset between the positions of the maximum heights of the bonding wires, i.e., in particular between the position of the maximum distance and the position of the further maximum distance along the connecting line or along the further connecting line is achieved between two adjacent bonding wires, i.e., in particular between the bonding wire and the further bonding wire, which have been bonded in diametrically opposed directions.

According to a preferred specific embodiment, it is provided that the bonding wire is situated between two further bonding wires, and/or that the further bonding wire is situated between two bonding wires. A plurality of bonding wires may thus be advantageously implemented, the average distance between two adjacent bonding wires being much greater in each case, compared to the conventional case. In particular, an installation space-saving connection of an evaluation chip having a capacitive sensor element is possible, for example using two, three, or four bonding wires which are situated side by side and which each have an improved signal-to-noise ratio.

According to a preferred specific embodiment, it is provided that one of the first or second semiconductor chips includes a micromechanical sensor and in particular a capacitive sensor, the other of the first or second semiconductor chips including an evaluation chip for the sensor, the sensor preferably being an acceleration sensor, a yaw rate sensor, and/or a pressure sensor.

A further subject matter of the present invention is a method for manufacturing a device. In an example embodiment, a bonding wire is manufactured in a first manufacturing step and a further bonding wire being manufactured in a second manufacturing step. The bonding wire and the further bonding wire are advantageously manufactured sequentially in such a way that the average distance between the bonding wire and the further bonding wire is substantially increased over that of the conventional case, as described above. This is achieved, for example, by manufacturing the bonding wire in the first manufacturing step, using a different loop height than the further bonding wire in the second manufacturing step.

According to a preferred specific embodiment, it is provided that, during the first manufacturing step, the first contact point to the first semiconductor chip is first produced and the second contact point to the second semiconductor chip is subsequently produced, while in the second manufacturing step, the further second contact point to the second semiconductor chip is first produced and the further first contact point to the first semiconductor chip is subsequently produced. The position of the maximum loop height (position of the maximum distance) of the bonding wire will thus advantageously differ from the position of the maximum loop height (position of the further maximum distance), since the position of the maximum loop height depends, among other things, on the starting point of the bonding operation. A manufacturing method of this type is advantageously programmable in standard automatic bonding machines.

### BRIEF DESCRIPTION OF THE DRAWINGS

Exemplary embodiments of the present invention are illustrated in the figures and explained in greater detail below.

FIGS. 1a, 1b, and c show schematic perspective views of conventional devices.

FIGS. 2a and 2b show schematic perspective views of devices according to a first and second specific embodiment of the present invention.

FIGS. 3a, 3b and 3c show schematic views of a device according to a third specific embodiment of the present invention.

FIGS. 4a and 4b show schematic illustrations of the dependencies between an offset drift and temperature in conventional devices and in devices according to the first specific embodiment of the present invention.

### DETAILED DESCRIPTION OF EXAMPLE EMBODIMENTS

In the figures, the same components are provided with the same reference numerals and are therefore, generally, also named or mentioned only once in each case.

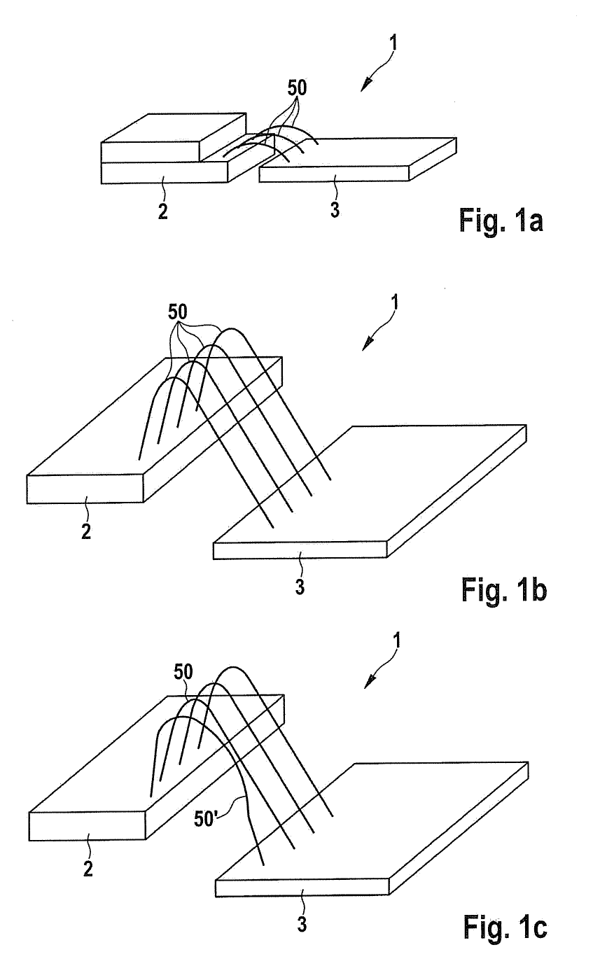

FIGS. 1a, 1b, and 1c show schematic perspective views of conventional devices 1. A first semiconductor chip 2 is connected in each case to a second semiconductor chip 3 in an electrically conductive manner, using a plurality of bonding wires 50. Bonding wires 50 are situated side by side and have largely the same loop heights, so that the distance between adjacent bonding wires 50 is generally constant over the entire length of bonding wires 50. FIG. 1c shows how in a system of this type, a deformation of a bonding wire 50′ produces a change in distance between this deformed bonding wire 50′ and an adjacent bonding wire 50 due to the thermal creep effect or mechanical shock during assembly or handling, there being a danger of dropping below the desired maximum distance between bonding wires 50′, 50 and, in particular a danger of a change in capacitance between bonding wires 50′ 50 being produced, which results in an offset drift.

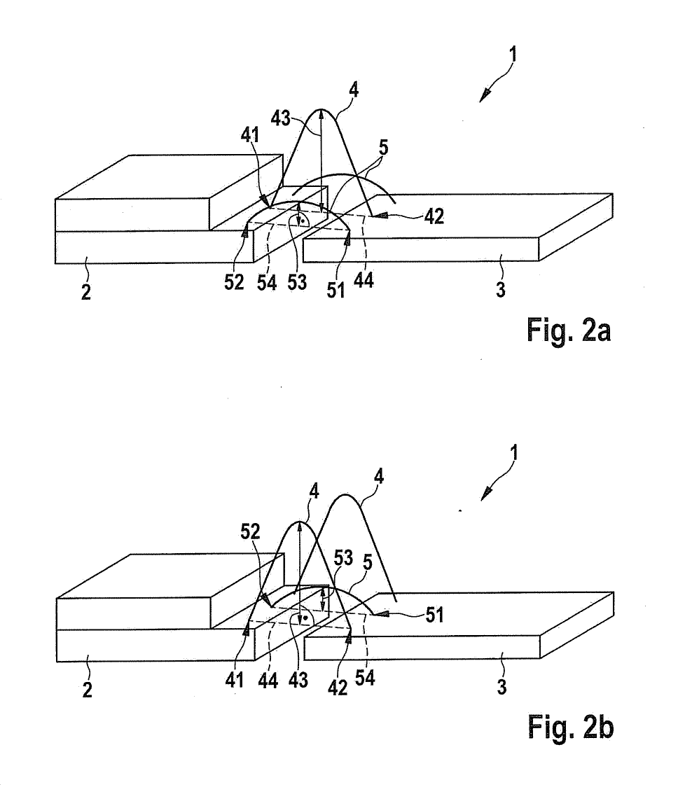

FIGS. 2a and 2b show schematic perspective views of devices 1 according to a first and second specific embodiment of the present invention. FIG. 2a shows a first and a second semiconductor chip 2,3, which are connected to each other in an electrically conductive manner via a bonding wire 4 and two further bonding wires 5, bonding wire 4 being situated between the two further bonding wires 5. Bonding wire 4 has a contact to first semiconductor chip 2 at a first contact point 41 and a contact to second semiconductor chip 3 at a second contact point 42. An imaginary connecting line 44 connects first and second contact points 41, 42 over the shortest distance. Similarly, each of further bonding wires 5 has a contact to first semiconductor chip 2 at a further first contact point 51 in each case and a contact to second semiconductor chip 3 at a further second contact point 52 in each case. An imaginary further connecting line 54 connects each of further first and second contact points 51, 52 over the shortest distance. A maximum distance 43 between connecting line 44 and bonding wire 4 perpendicularly to connecting line 44 is substantially greater than a corresponding further maximum distance 53 between further connecting line 54 and further bonding wire 5 perpendicularly to further connecting line 54. This means, in particular, that the loop height of bonding wire 4 is greater than the corresponding loop height of further bonding wire 5.

The average distance between bonding wire 4 and corresponding further bonding wire 5 is thus substantially increased compared to the conventional case without having to increase the pitch of first and/or second semiconductor chip 2, 3. First semiconductor chip 2 preferably includes a capacitive sensor, for example a yaw rate sensor, an acceleration sensor and/or a pressure sensor, manufactured by surface micromechanics or bulk micromechanics, while second semiconductor chip 3 preferably includes an evaluation chip for the capacitive sensor. FIG. 2b shows an alternative second specific embodiment which differs from the first specific embodiment illustrated in FIG. 2a only by the fact that a further bonding wire 5 is situated between two bonding wires 4.

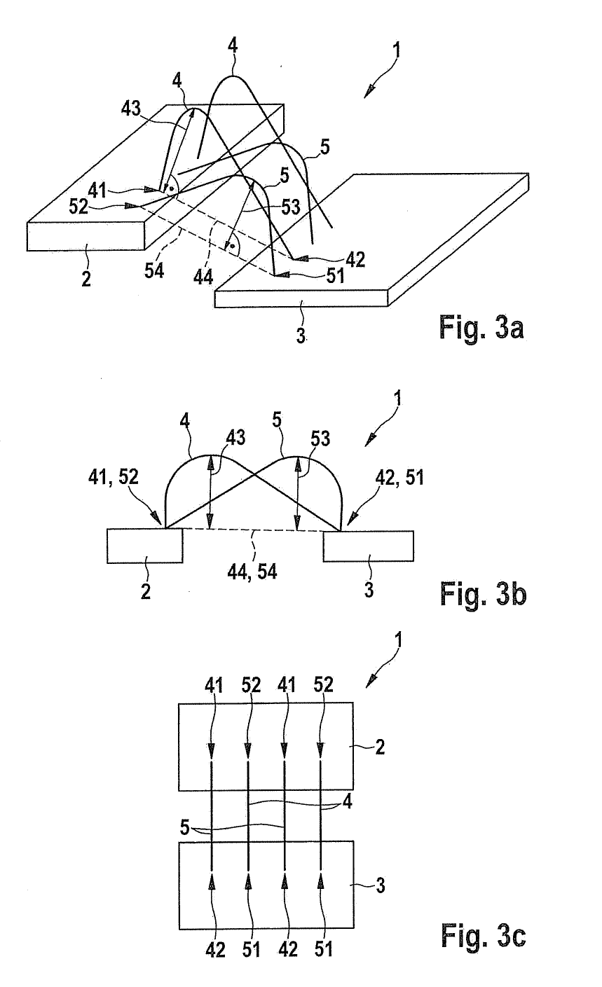

FIGS. 3a, 3b, and 3c show schematic perspective views, a schematic side view and a schematic top view of a device 1 according to a third specific embodiment of the present invention, the third specific embodiment largely resembling the first and second specific embodiments, the third and fourth specific embodiments each including two bonding wires and two further bonding wires, all of which have the same loop heights. A further bonding wire 5 is situated between two bonding wires 4 and a bonding wire 4 is situated between two further bonding wires 5. In contrast to FIGS. 2a and 2b, the positions of maximum distances 43 along connecting line 44 are also spaced a distance apart in relation to the position of further maximum distances 53 along further connecting line 54, parallel to connecting line 44 and to further connecting line 54. In other words, the maximum loop heights of adjacent bonding wires 4, 5 are offset in relation to each other. This is achieved by bonding bonding wires 4 and further bonding wires 5 in diametrically opposed directions, so that the starting points or “balls” of bonding wires 4 are situated on first semiconductor chip 2, and the starting points or “balls” of further bonding wires 5 are situated on second semiconductor chip 3.

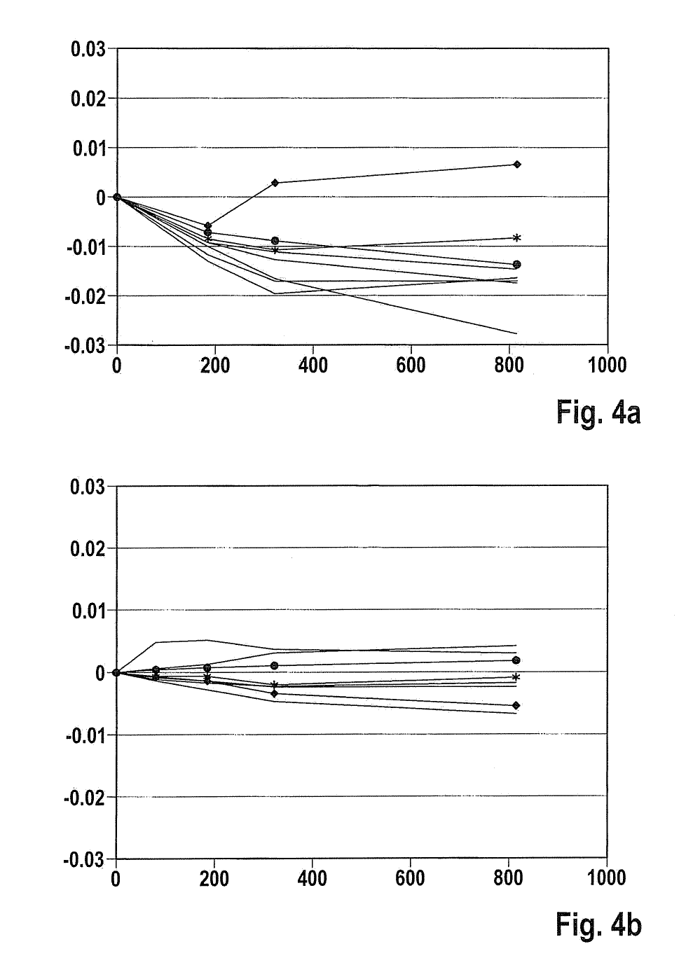

FIGS. 4a and 4b show schematic illustrations of the dependencies between an offset drift and temperature in conventional devices 1 and in devices 1 according to the first specific embodiment of the present invention, in each case the offset drift being plotted on the ordinate and the number of temperature changes being plotted on the abscissa. In each case, device 1 includes a low-g acceleration sensor as first semiconductor chip 2, which is connected via aluminum bonding wires to an evaluation chip as second semiconductor chip 3 and each of which is subjected to the specified number of temperature fluctuations between −40° and 140° C. FIG. 4a shows the scatter of offset drifts in devices 1 of this type according to the related art, and FIG. 4b shows the scatter of offset drifts in devices 1 according to the first specific embodiment of the present invention. It is apparent that the offset drive in device 1 according to the first specific embodiment is substantially lower.

What is claimed is:

1. A device, comprising:
a first semiconductor chip;
a second semiconductor chip;
a bonding wire, the first semiconductor chip and the second semiconductor chip being connected to each other in an electrically conductive manner via the bonding wire, the bonding wire having a contact to the first semiconductor chip at a first contact point and having a contact to the second semiconductor chip at a second contact point; and
a further bonding wire, the first semiconductor chip and the second semiconductor chip being connected to each other in an electrically conductive manner via the further bonding wire, the further bonding wire having a contact to the first semiconductor chip at a further first contact point and contact to the second semiconductor chip at a further second contact point;
wherein a maximum distance between the bonding wire and a direct connecting line between the first and second contact points perpendicularly to the connecting line is greater than a further maximum distance between the further bonding wire and a further connecting line between the further first and the further second contact points perpendicularly to the further connecting line.

2. The device as recited in claim 1, wherein the maximum distance is provided between the bonding wire and the direct connecting line between the first and second contact points perpendicularly to the connecting line, and a further maximum distance is provided between the further bonding wire and the further connecting line between the further first and the further second contact points perpendicularly to the further connecting line, a position of the maximum distance on the connecting line being located at a distance from a position of the further maximum distance on the further connecting line, at least one of along the connecting line and along the further connecting line.

3. The device as recited in claim 1, wherein the further maximum distance is no more than 75 percent of the maximum distance.

4. The device as recited in claim 3, wherein the further maximum distance is no more than 30 percent of the maximum distance.

5. The device as recited in claim 4, wherein the further maximum distance is no more than 10 percent of the maximum distance.

6. The device as recited in claim 1, wherein at least one of: i) a distance between the position of the maximum distance on the connecting line and the position of the further maximum distance on the further connecting line along the connecting line is at least 10 percent of a total length of the connecting line, and ii) the distance between the position of the maximum distance on the connecting line and the position of the further maximum distance on the further connecting line along the further connecting line is at least 10 percent of the total length of the further connecting line.

7. The device as recited in claim 1, wherein at least one of: i) a distance between the position of the maximum distance on the connecting line and the position of the further maximum distance on the further connecting line along the connecting line is at least 20 percent of a total length of the connecting line, and ii) the distance between the position of the maximum distance on the connecting line and the position of the further maximum distance on the further connecting line along the further connecting line is at least 20 percent of the total length of the further connecting line.

8. The device as recited in claim 1, wherein at least one of: i) a distance between the position of the maximum distance on the connecting line and the position of the further maximum distance on the further connecting line along the connecting line is at least 50 percent of a total length of the connecting line, and ii) the distance between the position of the maximum distance on the connecting line and the position of the further maximum distance on the further connecting line along the further connecting line is at least 50 percent of the total length of the further connecting line.

9. The device as recited in claim 1, wherein the further first contact point has a contact between the further bonding wire and the first semiconductor chip, and the further second contact point has a contact between the further bonding wire and the second semiconductor chip.

10. The device as recited in claim 1, wherein the bonding wire includes a ball/wedge bond, and the further bonding wire includes a further ball/wedge bond, the first contact point forming a ball of the ball/wedge bond and the second contact point forming a wedge of the ball/wedge bond, and the further first contact point forming a wedge of the further ball/wedge bond and the further second contact point forming a ball of the further ball/wedge bond.

11. The device as recited in claim 1, wherein at least one of the bonding wire is situated between two further bonding wires, and the further bonding wire is situated between two bonding wires.

12. The device as recited in claim 1, wherein one of the first and second semiconductor chips includes a capacitive sensor, the other of the first and second semiconductor chips including an evaluation chip for the sensor, the sensor including at least one of an acceleration sensor, a yaw rate sensor, and a pressure sensor.

13. A method for manufacturing a device, the device including a first semiconductor chip, a second semiconductor chip, a bonding wire, the first semiconductor chip and the second semiconductor chip being connected to each other in an electrically conductive manner via the bonding wire, the bonding wire having a contact to the first semiconductor chip at a first contact point and having a contact to the second semiconductor chip at a second contact point, and a further bonding wire, the first semiconductor chip and the second semiconductor chip being connected to each other in an electrically conductive manner via the further bonding wire, the further bonding wire having a contact to the first semiconductor chip at a further first contact point and a contact to the second semiconductor chip at a further second contact point, wherein a maximum distance between the bonding wire and a direct connecting line between the first and second contact points perpendicularly to the connecting line is greater than a further maximum distance between the further bonding wire and a further connecting line between the further first and the further second contact points perpendicularly to the further connecting line, the method comprising:
manufacturing the bonding wire in a first manufacturing step; and
manufacturing the further bonding wire in a second manufacturing step.

14. The method as recited in claim 13, wherein during the first manufacturing step, the first contact point to the first semiconductor chip is first produced and the second contact point to the second semiconductor chip is subsequently produced, while in the second manufacturing step, the further second contact point to the second semiconductor chip is first produced and the further first contact point to the first semiconductor chip is subsequently produced.
